(19) United States
(12) Patent Application Publication
(10) Pub. No.: US 2026/0255837 A1
(43) Pub. Date: Aug. 27, 2026

(54) DISPLAY MODULE AND ELECTRONIC DEVICE HAVING THE SAME HAVING IMPROVED LIGHT EXTRACTION EFFICIENCY AND BRIGHTNESS

(71) Applicant: SAMSUNG DISPLAY CO., LTD., YONGIN-SI (KR)

(72) Inventors: YANG-HO JUNG, Yongin-si (KR); YEONGWOO KWON, Yongin-si (KR); JIN-SU BYUN, Yongin-si (KR); GWANGMIN CHA, Yongin-si (KR)

(21) Appl. No.: 19/466,889

(22) Filed: Feb. 2, 2026

(30) Foreign Application Priority Data
Feb. 21, 2025 (KR) 10-2025-0023084

(51) Int. Cl. H10K 59/38; H10K 59/122; H10K 59/123; H10K 59/35; H10K 59/40; H10K 59/80

(52) U.S. Cl. CPC H10K 59/38; H10K 59/122; H10K 59/123; H10K 59/351; H10K 59/352; H10K 59/40; H10K 59/873

(57) ABSTRACT

A display module includes a light-emitting diode, an encapsulation layer, a lower sensing electrode, an input sensing insulating pattern, an upper sensing electrode, a color filter layer, and a top coating layer. The encapsulation layer covers the light-emitting diode. The lower sensing electrode is disposed on the encapsulation layer. A transmission opening is defined in the input sensing insulating pattern. The input sensing insulating pattern is disposed on the encapsulation layer and covers the lower sensing electrode. The input sensing insulating pattern includes an organic material. The upper sensing electrode is disposed on the input sensing insulating pattern. The color filter layer is disposed on the input sensing insulating pattern. The top coating layer is disposed on the color filter layer. A refractive index of the color filter layer is between refractive indices of the input sensing insulating pattern and the top coating layer.

### CROSS-REFERENCE TO RELATED APPLICATIONS

This application claims priority under 35 U.S.C § 119 to Korean Patent Application No. 10-2025-0023084 filed on Feb. 21, 2025 in the Korean Intellectual Property Office, the disclosure of which is incorporated by reference herein in its entirety.

### TECHNICAL FIELD

Embodiments of the present disclosure relate to a display module and an electronic device including the same with improved light extraction efficiency and brightness.

### DISCUSSION OF THE RELATED ART

When the light-emitting efficiency of a display module is improved, the battery life of an electronic device may be extended. The light-emitting efficiency of the display module may be enhanced by removing the polarizer from the display module and adding a color filter layer to the display module.

A user of the electronic device typically views the device from the front side. When the brightness of light emitted toward the front of the display module is improved, a greater amount of light can be presented to the user. To enhance the brightness of front-emitted light, an optical pattern may be applied to the display module.

However, when the optical pattern is applied on the color filter layer of the display module, external light may be reflected by the optical pattern. As a result, the screen displayed by the display module might not be properly presented to the user. Furthermore, when the optical pattern is applied underneath the color filter layer, the thickness of the optical pattern may reduce the viewing angle of the display module.

### SUMMARY

A display module includes a base, a light-emitting diode, an encapsulation layer, a lower sensing electrode, an input sensing insulating pattern, an upper sensing electrode, a color filter layer, and a top coating layer. The light-emitting diode is disposed on the base to emit light. The encapsulation layer covers the light-emitting diode. The lower sensing electrode is disposed on the encapsulation layer. The input sensing insulating pattern has a transmission opening defined therein. The input sensing insulating pattern is disposed on the encapsulation layer and covers the lower sensing electrode. The input sensing insulating pattern includes an organic material. The upper sensing electrode is disposed on the input sensing insulating pattern. The color filter layer is disposed on the input sensing insulating pattern. The top coating layer is disposed on the color filter layer. The refractive index of the color filter layer is between the refractive index of the input sensing insulating pattern and the refractive index of the top coating layer.

At least a portion of the color filter layer may be disposed within the transmission opening.

The display module may further include a pixel defining layer. The pixel defining layer may be disposed on the base and may have a light-emitting opening defined therein. The transmission opening may overlap the pixel defining layer in a thickness direction of the display module.

A portion of an upper surface of the color filter layer that overlaps the transmission opening in a thickness direction of the display module may be spaced apart from an upper surface of the encapsulation layer by a first distance. Another portion of the upper surface of the color filter layer that does not overlap the transmission opening in the thickness direction of the display module may be spaced apart from the upper surface of the encapsulation layer by a second distance greater than the first distance.

The portion of the upper surface of the color filter layer that overlaps the transmission opening in the thickness direction of the display module may include a curved surface.

A flatness of an upper surface of the top coating layer may be greater than a flatness of a lower surface of the top coating layer.

The display module may further include an input sensing driving circuit that detects a change in capacitance formed between an external object and each of the lower sensing electrode and the upper sensing electrode.

The refractive index of the input sensing insulating pattern may be smaller than that of the top coating layer. The input sensing insulating pattern might not overlap in the thickness direction of the display module the light-emitting opening.

The refractive index of the input sensing insulating pattern may be greater than or equal to 1.30 and smaller than or equal to 1.55; the refractive index of the color filter layer may be greater than 1.55 and smaller than or equal to 1.63; and the refractive index of the top coating layer may be greater than 1.63 and smaller than or equal to 1.90.

The display module may further include a sub-input sensing insulating pattern. The sub-input sensing insulating pattern may have a sub-transmission opening defined therein that overlaps the transmission opening in the thickness direction of the display module. The sub-input sensing insulating pattern might not overlap the lower sensing electrode in the thickness direction of the display module. The sub-input sensing insulating pattern may be disposed on the input sensing insulating pattern.

A refractive index of the input sensing insulating pattern may be greater than that of the top coating layer. The input sensing insulating pattern may overlap the light-emitting opening in the thickness direction of the display module.

The refractive index of the input sensing insulating pattern may be greater than 1.63 and smaller than or equal to 1.90; the refractive index of the color filter layer may be greater than 1.55 and smaller than or equal to 1.63; and the refractive index of the top coating layer may be greater than or equal to 1.30 and smaller than or equal to 1.55.

The display module may further include a sub-input sensing insulating pattern. The sub-input sensing insulating pattern may have a sub-transmission opening defined therein that overlaps the input sensing insulating pattern in the thickness direction of the display module and may overlap the transmission opening in the thickness direction of the display module. The sub-input sensing insulating pattern may be disposed on the encapsulation layer. A distance between an upper surface of the input sensing insulating pattern and an upper surface of the encapsulation layer may be smaller than a distance between an upper surface of the sub-input sensing insulating pattern and the upper surface of the encapsulation layer.

The display module may further include an input sensing protection layer. The input sensing protection layer may cover the input sensing insulating pattern and the upper sensing electrode. The input sensing protection layer may be disposed between the input sensing insulating pattern and the color filter layer. The refractive index of the input sensing protection layer may be between the refractive index of the input sensing insulating pattern and that of the color filter layer.

The light-emitting diode may include a first light-emitting diode, a second light-emitting diode, and a third light-emitting diode. The first light-emitting diode may emit light of a first wavelength. The second light-emitting diode may emit light of a second wavelength. The third light-emitting diode may emit light of a third wavelength. The color filter layer may include a first color filter, a second color filter, and a third color filter. The first color filter may transmit the light of the first wavelength and may block the light of the second wavelength and the third wavelength. The second color filter may transmit the light of the second wavelength and may block the light of the first wavelength and the third wavelength. The third color filter may transmit the light of the third wavelength and may block the light of the first wavelength and the second wavelength. The first color filter may overlap the first light-emitting diode in the thickness direction of the display module. The second color filter may overlap with the second light-emitting diode in the thickness direction of the display module. The third color filter may overlap the third light-emitting diode in the thickness direction of the display module.

An electronic device includes a base, a light-emitting diode, an encapsulation layer, a lower sensing electrode, an input sensing insulating pattern, an upper sensing electrode, a color filter layer, and a top coating layer. The light-emitting diode is disposed on the base. The encapsulation layer covers the light-emitting diode. The lower sensing electrode is disposed on the encapsulation layer. The input sensing insulating pattern has a transmission opening defined therein. The input sensing insulating pattern is disposed on the encapsulation layer and covers the lower sensing electrode. The upper sensing electrode is disposed on the input sensing insulating pattern. The color filter layer is disposed on the input sensing insulating pattern. The top coating layer is disposed on the color filter layer. A portion of the top coating layer that overlaps the transmission opening in a thickness direction of the electronic device has a first thickness, and a portion of the top coating layer that does not overlap the transmission opening in the thickness direction of the electronic device has a second thickness smaller than the first thickness. The refractive index of the color filter layer is between the refractive index of the input sensing insulating pattern and that of the top coating layer.

A portion of a lower surface of the top coating layer that overlaps the transmission opening in the thickness direction of the electronic device may be spaced apart from an upper surface of the encapsulation layer by a first distance. A portion of the lower surface of the top coating layer that does not overlap the transmission opening in the thickness direction of the electronic device may be spaced apart from the upper surface of the encapsulation layer by a second distance greater than the first distance. A sum of the first thickness and the first distance and a sum of the second thickness and the second distance may be substantially equal.

A portion of the lower surface of the top coating layer that overlaps the transmission opening in the thickness direction of the electronic device may include a curved surface.

The electronic device may further include a pixel defining layer. The pixel defining layer may be disposed on the base and may have a light-emitting opening defined therein. The refractive index of the input sensing insulating pattern may be smaller than that of the top coating layer. The transmission opening may overlap the light-emitting opening in the thickness direction of the electronic device.

The electronic device may further include a pixel defining layer. The pixel defining layer may be disposed on the base and may have a light-emitting opening defined therein. The refractive index of the input sensing insulating pattern may be greater than that of the top coating layer. The transmission opening might not overlap the light-emitting opening in the thickness direction of the electronic device.

A display module and an electronic device including the same may be provided in which light-emitting efficiency and brightness of light emitted toward the front are improved by an input sensing portion and an antireflection layer.

A display module and an electronic device including the same may be provided in which the light-emitting efficiency is enhanced by an antireflection layer including a color filter layer.

A display module and an electronic device including the same may be provided in which the brightness of light emitted toward the front is improved by an input sensing portion including an input sensing insulating pattern and an antireflection layer including a color filter layer and a top coating layer.

### BRIEF DESCRIPTION OF THE DRAWINGS

The above and other features of the present disclosure will become more apparent by describing embodiments thereof in detail with reference to the accompanying drawings in which:

FIG. 1 illustrates an example of a display device according to an embodiment of the present disclosure;

FIG. 2 is a cross-sectional view schematically illustrating a display device according to an embodiment of the present disclosure;

FIG. 3 is a plan view schematically illustrating a display module according to an embodiment of the present disclosure;

FIG. 4 is an example equivalent circuit diagram of a pixel according to an embodiment of the present disclosure;

FIG. 5 is a diagram schematically illustrating a light-emission control signal and scan signals applied to the pixel shown in FIG. 4;

FIG. 6 is a plan view schematically illustrating one of a plurality of pixels according to an embodiment of the present disclosure;

FIG. 7 is a cross-sectional view schematically illustrating a display module according to an embodiment of the present disclosure;

FIG. 8 is an enlarged view showing specific configurations within region AA of FIG. 7 in more detail;

FIG. 9 illustrates an optical path in the enlarged view of region AA of FIG. 7;

FIG. 10 is a flowchart illustrating a method of manufacturing a display module according to an embodiment of the present disclosure;

FIGS. 11A to 11E are cross-sectional views schematically illustrating respective steps of the method of manufacturing a display module according to an embodiment of the present disclosure;

FIG. 12A is a cross-sectional view schematically illustrating a display module according to an embodiment of the present disclosure;

FIG. 12B illustrates an optical path in an enlarged view of region AA of FIG. 12A;

FIG. 13A is a cross-sectional view schematically illustrating a display module according to an embodiment of the present disclosure;

FIG. 13B illustrates an optical path in an enlarged view of region AA of FIG. 13A;

FIG. 14A is a cross-sectional view schematically illustrating a display module according to an embodiment of the present disclosure;

FIG. 14B illustrates an optical path in an enlarged view of region AA of FIG. 14A;

FIGS. 15 and 16 are cross-sectional views schematically illustrating a display module according to an embodiment of the present disclosure;

FIG. 17 is a block diagram illustrating an electronic device according to an embodiment of the present disclosure; and

FIG. 18 illustrates various examples of an electronic device according to embodiments of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not necessarily limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

The terms of a singular form may include plural forms unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

The terms “about” or “approximately” as used herein are inclusive of the stated value and means within an acceptable range of deviation for the particular value as determined by one of ordinary skill in the art, considering the measurement in question and the error associated with measurement of the particular quantity (e.g., the limitations of the measurement system). For example, “about” or “approximately” can mean within one or more standard deviations, or within, for example, ±30%, 20%, 10% or 5% of the stated value.

An expression such as “comprising” or “including” is intended to designate a characteristic, a number, a step, an operation, an element, a part, or combinations thereof, and shall not be construed to preclude any possibility of presence or addition of one or more other characteristics, numbers, steps, operations, elements, parts, or combinations thereof.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

A display device according to an embodiment may be applied to various types of electronic devices. An electronic device according to an embodiment may include the display device described above and may further include other modules or devices having additional functions.

As used herein, the term “overlap” refers to an arrangement in the direction normal to a surface of a component such as in a thickness direction of a display device or a display module, and is not necessarily limited to an arrangement in which the components are located directly above or below one another. The term “overlap” may further include a configuration in which a portion of one component overlaps with another component.

Embodiments of the disclosure provide a display module and an electronic device that improves light extraction efficiency and brightness. This is achieved by eliminating the polarizer, and by adjusting the shapes and indices of refraction of layers in an input sensing portion disposed over a display panel and in an antireflection layer disposed on the input sensing portion. On some embodiments, layers of the combination of the input sensing portion and the anti-reflection layer may progressively have higher indices of refraction in going from a display panel to an outside of the display module from which the image is viewed. As a result, rays produced in a light emitting element in the display panel may be totally reflected by sidewalls of layers in the input sensing portion, and at other layer interfaces may be refracted towards a normal direction of an output surface of the display module.

Also, the color filter layer of the anti-reflection layer may include an organic insulating material having a concave upper surface thereof when viewed in a direction opposite from the third direction DR3 from a top side that mates with a corresponding convex protrusion of an top coating layer having a higher index of refraction when viewed in the third direction DR3 from a bottom side. Consequently, this interface between the top surface of the color filter layer and the bottom surface of the top coating layer produces a lens through which light produced by the display panel passes through before exiting the display module, further improving light extraction efficiency and brightness.

FIG. 1 illustrates an example of a display device DD according to an embodiment of the present disclosure. Referring to FIG. 1, the display device DD may have a display area DA and a non-display area NDA defined therein. The display device DD may be a smartphone.

The directions indicated by first to third directional axes DR1, DR2, DR3 are relative and may be reoriented. Hereinafter, the first to third directions DR1, DR2, DR3 are denoted by the same reference symbols indicated by the corresponding directional axes DR1, DR2, DR3.

The display area DA may be an area where images are displayed on the display device DD. Light may be emitted from the display area DA. A screen may be rendered in the display area DA by light emitted from a plurality of light-emitting diodes.

The non-display area NDA may be an area of the display device DD where images are not displayed. Light might not be emitted from the non-display area NDA. The non-display area NDA may surround the display area DA.

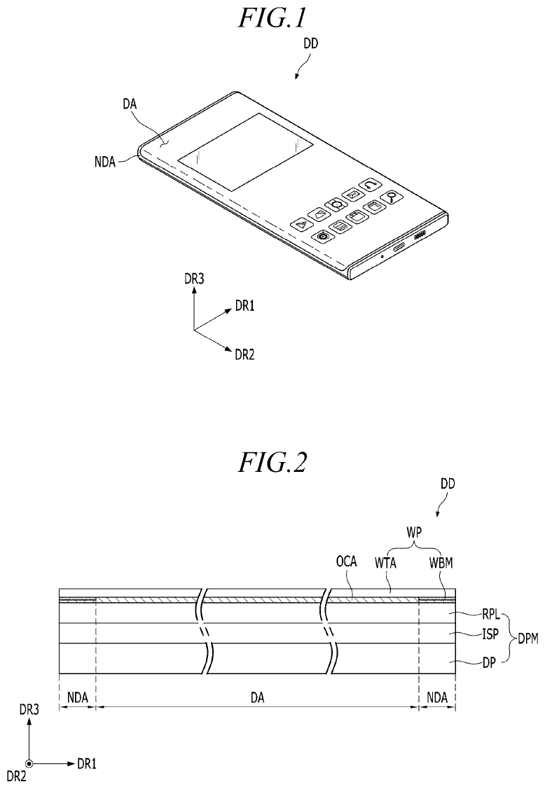

FIG. 2 is a cross-sectional view schematically illustrating a display device DD according to an embodiment of the present disclosure. Referring to FIG. 2, the display device DD may include a display module DPM, a window WP, and an adhesive portion OCA. In FIG. 2, the stacked structure of the display device DD is illustrated in a simplified form.

The display module DPM may include a display panel DP, an input sensing portion ISP, and an antireflection layer RPL. The display module DPM may be configured to emit light toward the window WP.

The display panel DP may be configured to emit light and may be of a light-emitting type. The display panel DP may be an organic light-emitting display panel, a quantum dot light-emitting display panel, or a micro light-emitting display panel. The display panel DP may include a plurality of light-emitting diodes.

The input sensing portion ISP may be disposed on the display panel DP and may be configured to acquire coordinate information of an external input. For example, at least one of a capacitive-type input sensor, resistive film-type input sensor, optical sensor, electromagnetic resonance-type input sensor, ultrasonic input sensor, and infrared input sensor may be used in the input sensing portion ISP.

Due to the input sensing portion ISP, a path of light emitted from the display panel DP may be changed. For example, the light may be refracted or reflected. Light whose path is changed by the input sensing portion ISP may be directed toward the front of the display module DPM, i.e., along the third direction DR3.

The antireflection layer RPL may be disposed on the input sensing portion ISP and may be configured to reduce a reflectance of external light incident from above the window WP. The antireflection layer RPL according to an embodiment of the present disclosure may include a color filter layer.

Moreover, due to the antireflection layer RPL, a path of light emitted from the display panel DP may be changed. The light whose path is changed by the antireflection layer RPL may be directed toward the front of the display module DPM, i.e., along the third direction DR3.

The window WP may be disposed on the antireflection layer RPL and may include a transmissive portion WTA and a light-blocking portion WBM.

The transmissive portion WTA may overlap (i.e., overlap in a thickness direction of the display module DPM) with the display area DA and may include glass and/or synthetic resin. The transmissive portion WTA is not necessarily limited to a single layer and may include two or more films bonded by an adhesive. The transmissive portion WTA may be configured to transmit light emitted from the display panel DP.

The light-blocking portion WBM may overlap with the non-display area NDA and may partially overlap with the transmissive portion WTA. The light-blocking portion WBM may be disposed on a rear surface of the transmissive portion WTA and may be configured to block light emitted from the display panel DP.

The adhesive portion OCA may be disposed between the display module DPM and the window WP and may be configured to bond the display module DPM with the window WP. An upper surface of the display module DPM may be flat, thereby allowing the display module DPM and the window WP to be bonded more readily with each other via the adhesive portion OCA.

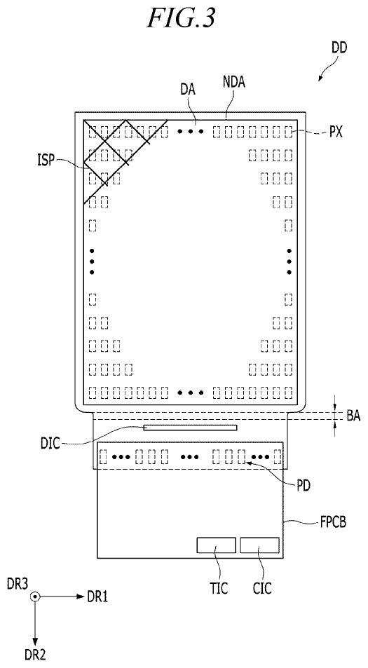

FIG. 3 is a plan view schematically illustrating a display module DPM according to an embodiment of the present disclosure. The display module DPM may have a display area DA and a non-display area NDA defined therein. The non-display area NDA may be defined along the periphery of the display area DA. The display area DA may correspond to the display area DA of the display device DD shown in FIG. 1, and the non-display area NDA may correspond to the non-display area NDA of the display device DD shown in FIG. 1.

The display module DPM may include a plurality of pixels PX, a data driving circuit DIC, a plurality of pads PD, an input sensing portion ISP, a flexible printed circuit board FPCB, an input sensing driving circuit TIC, and a control driving circuit CIC.

The data driving circuit DIC may be electrically connected to the pixels PX in the display area DA and may be configured to provide data signals to the pixels PX.

The input sensing driving circuit TIC and the control driving circuit CIC may be mounted on the flexible printed circuit board FPCB and may be configured to receive electrical signals from the plurality of pads PD.

The input sensing driving circuit TIC may be electrically connected to the input sensing portion ISP via the plurality of pads PD. The input sensing driving circuit TIC may be configured to process signals corresponding to a change in current caused by a user's touch applied to the display area DA or pressure applied from an external source.

For example, the input sensing portion ISP may be a capacitive-type input sensor including upper and lower sensing electrodes. Capacitance formed between the upper and lower sensing electrodes and another object may vary due to a user's touch or external input. The input sensing driving circuit TIC may be configured to detect a change in the capacitance formed between the upper and lower sensing electrodes and the external object, and to process the user's touch or external input signal.

The control driving circuit CIC may be a circuit configured for controlling at least one of the data driving circuit DIC and the input sensing driving circuit TIC.

The display panel DP may be configured to be bent about a bending area BA.

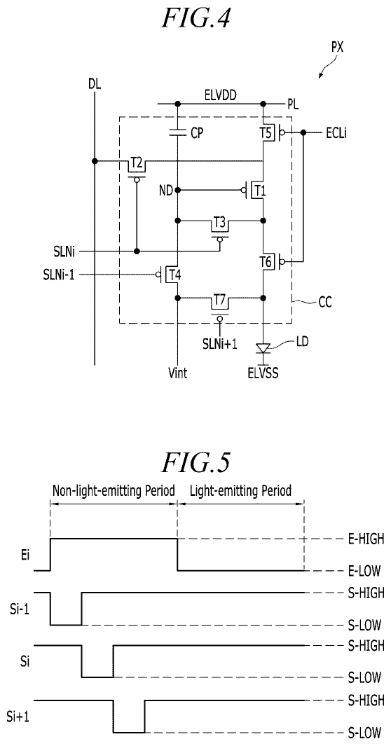

FIG. 4 is an example equivalent circuit diagram of a pixel PX according to an embodiment of the present disclosure. FIG. 5 schematically illustrates a light-emission control signal Ei and scan signals Si−1, Si, Si+1 applied to the pixel PX shown in FIG. 4 where i is a natural number. FIG. 4 exemplifies a pixel PX connected to an i-th scan line SLNi and an i-th light-emission control line ECLi where i is a natural number.

The pixel PX may include an organic light-emitting diode OLED and a pixel circuit CC. The pixel circuit CC may include a plurality of transistors T1-T7 and a capacitor CP. The pixel circuit CC is configured to control an amount of current flowing through the organic light-emitting diode OLED in response to a data signal. The organic light-emitting diode OLED may be configured to emit light at a predetermined brightness based on the amount of current supplied by the pixel circuit CC. To this end, the level of a first power supply ELVDD may be set higher than that of a second power supply ELVSS.

Each of the plurality of transistors T1-T7 may include an input electrode (or source electrode), an output electrode (or drain electrode), and a control electrode (or gate electrode). For convenience, in this specification, one of the input electrode and the output electrode may be referred to as a first electrode, and the other as a second electrode.

The first electrode of the first transistor T1 is connected to the first power supply ELVDD via the fifth transistor T5, and the second electrode is connected to the anode electrode of the organic light-emitting diode OLED via the sixth transistor T6. In this specification, the first transistor T1 may be referred to as a driving transistor. The first transistor T1 is configured to control an amount of current flowing through the organic light-emitting diode OLED based on a voltage applied to the control electrode.

The second transistor T2 is connected between a data line DL and the first electrode of the first transistor T1. The control electrode of the second transistor T2 is connected to the i-th scan line SLNi. The second transistor T2 is configured to turn on when the i-th scan signal Si is applied via the i-th scan line SLNi, thereby electrically connecting the data line DL with the first electrode of the first transistor T1.

The third transistor T3 is connected between the second electrode and the control electrode of the first transistor T1. The control electrode of the third transistor T3 is connected to the i-th scan line SLNi. When the i-th scan signal Si is provided to the i-th scan line SLNi, the third transistor T3 is configured to turn on to electrically connect the second electrode and control electrode of the first transistor T1, causing the first transistor T1 to be connected in a diode configuration when the third transistor T3 turns on.

The fourth transistor T4 is connected between a node ND and an initialization power supply generator. The control electrode of the fourth transistor T4 is connected to the (i−1)-th scan line SLNi−1. When the (i−1)-th scan signal Si−1 is provided to the (i−1)-th scan line SLNi−1, the fourth transistor T4 turns on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the organic light-emitting diode OLED. The control electrode of the sixth transistor T6 is connected to the i-th light-emission control line ECLi.

The seventh transistor T7 is connected between the initialization power supply generator and the anode electrode of the organic light-emitting diode OLED. The control electrode of the seventh transistor T7 is connected to the (i+1)-th scan line SLNi−1. When the (i+1)-th scan signal Si+1 is provided to the (i+1)-th scan line SLNi+1, the seventh transistor T7 turns on to supply the initialization voltage Vint to the anode electrode of the organic light-emitting diode OLED.

The seventh transistor T7 may be configured to improve black level performance of the pixel PX. For example, when the seventh transistor T7 turns on, the parasitic capacitor of the OLED is discharged, preventing undesired light emission caused by leakage current from the first transistor T1, thereby enhancing black representation.

Although FIG. 4 shows that the control electrode of the seventh transistor T7 is connected to the (i+1)-th scan line SLNi+1, the disclosure is not necessarily limited to this configuration. In other embodiments, the control electrode of the seventh transistor T7 may be connected to the i-th scan line SLNi or the (i−1)-th scan line SLNi−1.

Furthermore, while FIG. 4 is illustrated for PMOS transistors, this is not limiting, either. In other embodiments, the pixel PX may be composed of NMOS transistors or a combination of NMOS and PMOS transistors.

The capacitor CP is disposed between the power line PL and the node ND and is configured to store a voltage corresponding to the data signal. The voltage stored in the capacitor CP determines the current flowing through the first transistor T1 when the fifth transistor T5 and sixth transistor T6 are turned on. The structure of the pixel PX is not necessarily limited to that illustrated in FIG. 4 and may be implemented in various configurations suitable for driving the organic light-emitting diode OLED.

Referring to FIG. 5, the light-emission control signal Ei may have a high level E-HIGH or a low level E-LOW. The scan signals Si−1, Si, and Si+1 may each have a high level S-HIGH or a low level S-LOW.

When the light-emission control signal Ei is at a high level E-HIGH, the fifth transistor T5 and sixth transistor T6 are turned off, causing the power line PL and the first electrode of the first transistor T1 to be electrically isolated. When the sixth transistor T6 is turned off, the second electrode of the first transistor T1 and the anode electrode of the OLED is electrically isolated. Therefore, while the light-emission control signal Ei having a high level E-HIGH is provided to the i-th light-emission control line ECLi, the OLED does not emit light.

Next, when the (i−1)-th scan signal Si−1 provided to the (i−1)-th scan line SLNi−1 has a low level S-LOW, the fourth transistor T4 turns on, leading the initialization voltage Vint to be provided to the node ND. When the i-th scan signal Si provided to the i-th scan line SLNi has a low level S-LOW, the second and third transistors T2, T3 turn on. When the second transistor T2 turns on, the data signal is provided to the first electrode of the first transistor T1. Here, the first transistor T1 turns on because the node ND is initialized to the initial voltage Vint. When the first transistor T1 is turned on, a voltage corresponding to the data signal is provided to the node ND, at which time the capacitor CP stores the voltage corresponding to the data signal.

When the (i+1)-th scan signal Si+1 provided to the (i+1)-th scan line SLNi+1 has a low level S-LOW, the seventh transistor T7 turns on, leading the initialization voltage Vint to be provided to the anode electrode of the OLED and the parasitic capacitor to be discharged.

When the light-emission control signal Ei provided to the light-emission control line ECLi is at a low level E-LOW, the fifth and sixth transistors T5, T6 are turned on. When the fifth transistor T5 turns on, the first power supply ELVDD is provided to the first electrode of the first transistor T1. When the sixth transistor T6 turns on, the second electrode of the first transistor T1 and the anode electrode of the OLED are electrically connected, causing the OLED to generate light of a predetermined brightness corresponding to the amount of current provided to the OLED.

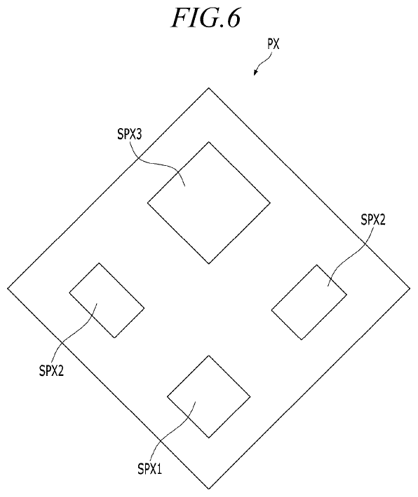

FIG. 6 is a plan view schematically illustrating one of a plurality of pixels PX according to an embodiment of the present disclosure. Referring to FIG. 6, each of the plurality of pixels PX may include a first subpixel SPX1, two second subpixels SPX2, and a third subpixel SPX3. The plurality of subpixels SPX1, SPX2, SPX3 may be configured to emit light having different wavelength ranges.

The first subpixel SPX1 may be configured to emit light of a first wavelength, which may be red light. The first wavelength may range from 620 nm to 750 nm.

The two second subpixels SPX2 may be configured to emit light of a second wavelength, which may differ from the first wavelength. The second wavelength may correspond to green light and may range from 500 nm to 570 nm.

The third subpixel SPX3 may be configured to emit light of a third wavelength, which may differ from both the first and second wavelengths. The third wavelength may correspond to blue light and may range from 450 nm to 500 nm.

In FIG. 6, the pixel PX is illustrated in a diamond pixel arrangement in which the plurality of subpixels SPX1, SPX2, SPX3 are disposed in a diamond structure. However, the shape of the pixel PX is not necessarily limited to this arrangement. In other embodiments, the pixel PX may have a stripe pixel arrangement, in which the subpixels SPX1, SPX2, SPX3 may be formed in rectangular shapes and arranged in a linear sequence. Furthermore, the numbers of the first, second, and third subpixels SPX1, SPX2, SPX3 are not necessarily limited to those described and shown herein. The first, second, and third subpixels SPX1, SPX2, SPX3 may each be provided singularly or in plurality.

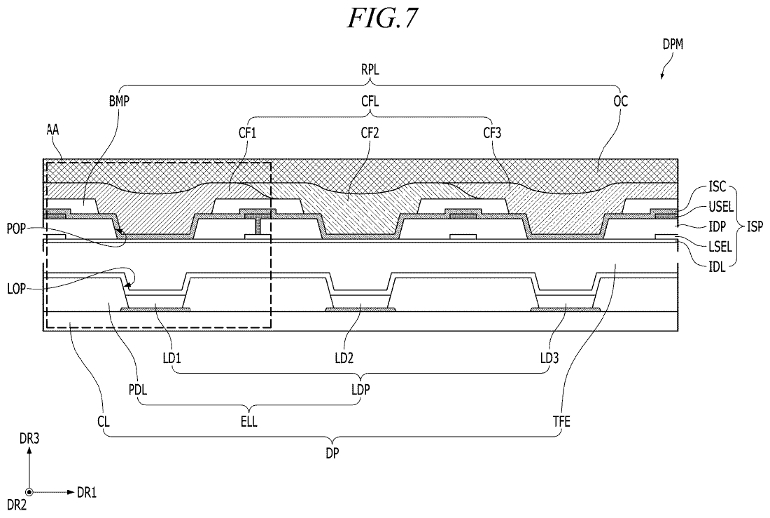

FIG. 7 is a cross-sectional view schematically illustrating a display module DPM according to an embodiment of the present disclosure. Referring to FIG. 7, the display module DPM may include a display panel DP, an input sensing portion ISP, and an antireflection layer RPL. In FIG. 7, the display panel DP may be illustrated in a simplified form.

The display panel DP may include a circuit layer CL, a light-emitting diode layer ELL, and an encapsulation layer TFE. Light may be emitted from the display panel DP.

The circuit layer CL may be configured to transmit electrical signals. The electrical signals transmitted from the circuit layer CL may be transferred to the light-emitting diode layer ELL. The configuration of the circuit layer CL will be described in more detail with reference to other drawings.

The light-emitting diode layer ELL may include a pixel defining layer PDL and a light-emitting diode LDP. The light-emitting diode layer ELL may be disposed on the circuit layer CL and may be configured to emit light by receiving electrical signals from the circuit layer CL.

The pixel defining layer PDL may be disposed on the circuit layer CL and may define a plurality of light-emitting openings LOP. Each of the plurality of light-emitting openings LOP may define a corresponding subpixel SPX1, SPX2, SPX3.

The light-emitting diode LDP may include a first light-emitting diode LD1, a second light-emitting diode LD2, and a third light-emitting diode LD3. The light-emitting diode LDP may be disposed on the circuit layer CL, and at least a portion of the light-emitting diode LDP may be disposed within the plurality of light-emitting openings LOP. The light-emitting diode LDP may be configured to emit light.

The first light-emitting diode LD1 may be disposed within one of the plurality of light-emitting openings LOP that defines the first subpixel SPX1. The first light-emitting diode LD1 may be a part of the light-emitting diode LDP disposed within the light-emitting opening LOP that defines the first subpixel SPX1. The first light-emitting diode LD1 may be configured to emit light of a first wavelength.

The second light-emitting diode LD2 may be disposed within one of the plurality of light-emitting openings LOP that defines the second subpixel SPX2. The second light-emitting diode LD2 may be a part of the light-emitting diode LDP disposed within the light-emitting opening LOP that defines the second subpixel SPX2. The second light-emitting diode LD2 may be configured to emit light of a second wavelength.

The third light-emitting diode LD3 may be disposed within one of the plurality of light-emitting openings LOP that defines the third subpixel SPX3. The third light-emitting diode LD3 may be a part of the light-emitting diode LDP disposed within the light-emitting opening LOP that defines the third subpixel SPX3. The third light-emitting diode LD3 may be configured to emit light of a third wavelength.

For example, the plurality of light-emitting diodes LD1, LD2, LD3 may be configured to emit light having different wavelengths. In other words, the light-emitting diodes LD1, LD2, LD3 may include different types of light-emitting materials. Additionally, the specific structures of the light-emitting diodes LD1, LD2, LD3 may also differ. For example, the thicknesses of the light-emitting diodes LD1, LD2, LD3 may be different from each other.

Nevertheless, the layer structures constituting each of the light-emitting diodes LD1, LD2, LD3 may be the same. For example, each of the light-emitting diodes LD1, LD2, LD3 may include an anode electrode, a hole functional layer, a light-emitting layer, an electron functional layer, and a cathode electrode. The configuration of the light-emitting diodes LD1, LD2, LD3 will be illustrated in more detail in other drawings.

The encapsulation layer TFE may be disposed on the light-emitting diode LDP and may cover the light-emitting diode LDP. The encapsulation layer TFE may be configured to protect the light-emitting diode LDP from external oxygen or moisture by sealing the light-emitting diode LDP. The configuration of the encapsulation layer TFE will be illustrated in greater detail in other drawings.

The input sensing portion ISP may include an input sensing insulating layer IDL, a lower sensing electrode LSEL, an input sensing insulating pattern IDP, an upper sensing electrode USEL, and an input sensing protection layer ISC. The input sensing portion ISP may include a capacitive-type input sensor.

The input sensing insulating layer IDL may be disposed on the encapsulation layer TFE and may be configured to protect the encapsulation layer TFE from external impact. The input sensing insulating layer IDL may have a single-layer or multilayer structure and may include an inorganic material or a composite material. The inorganic material may include at least one of aluminum oxide, titanium oxide, silicon oxide, silicon oxynitride, zirconium oxide, and hafnium oxide. In another embodiment, the input sensing insulating layer IDL may be replaced with an organic insulating layer. Alternatively, the input sensing insulating layer IDL may be omitted.

The lower sensing electrode LSEL may be disposed on the input sensing insulating layer IDL and may include a metal layer or a transparent electrode. The metal layer may include molybdenum, silver, titanium, copper, aluminum, or an alloy thereof. The transparent electrode may include a transparent conductive oxide such as indium tin oxide (ITO), indium zinc oxide (IZO), zinc oxide (ZnO), or indium tin zinc oxide (ITZO).

The input sensing insulating pattern IDP may be disposed on the input sensing insulating layer IDL and may cover the lower sensing electrode LSEL. The input sensing insulating pattern IDP may have a plurality of transmission openings POP defined therein. The input sensing insulating pattern IDP may overlap with the pixel defining layer PDL and might not overlap with the plurality of light-emitting openings LOP. The input sensing insulating pattern IDP may be an optical pattern.

The input sensing insulating pattern IDP may include an organic material and may include an acrylic-based polymer. The input sensing insulating pattern IDP may further include a refractive index modifier, which may include a refractive index increasing agent and a refractive index reducing agent.

The refractive index increasing agent may be a particulate high-refractive-index material and may include at least one of titanium oxide particles and zirconium oxide particles.

The refractive index reducing agent may be a particulate low-refractive-index material and may include at least one of hollow silica, low-refractive-index polymer particles, air bubbles, and pore.

The input sensing insulating pattern IDP may have a first refractive index. The first refractive index may have a value greater than or equal to 1.30 and smaller than or equal to 1.55. The first refractive index may be smaller than second through fourth refractive indices, which will be described later. The first refractive index may be a low refractive index. The input sensing insulating pattern IDP may be a low-refractive-index optical pattern.

The plurality of transmission openings POP may overlap with the pixel defining layer PDL. An inner surface of the input sensing insulating pattern IDP that defines the plurality of transmission openings POP may overlap with the pixel defining layer PDL.

The upper sensing electrode USEL may be disposed on the input sensing insulating pattern IDP. The detailed configuration of the upper sensing electrode USEL may be the same as that of the lower sensing electrode LSEL. At least a portion of the upper sensing electrode USEL may overlap with the lower sensing electrode LSEL. The upper sensing electrode USEL may be electrically connected to the lower sensing electrode LSEL.

The input sensing protection layer ISC may cover the input sensing insulating pattern IDP and the upper sensing electrode USEL. The input sensing protection layer ISC may be configured to protect the input sensing insulating pattern IDP and the upper sensing electrode USEL and may have excellent chemical resistance.

The input sensing protection layer ISC may include an inorganic material. The input sensing protection layer ISC may include at least one of silicon nitride, silicon oxide, and silicon oxynitride.

The input sensing protection layer ISC may have a second refractive index. The value of the second refractive index may be greater than the value of the first refractive index. Therefore, light emitted from the light-emitting diode LDP may be refracted at an interface between the input sensing insulating pattern IDP and the input sensing protection layer ISC. For example, the path of the light may change at the inner surface that defines the transmission opening POP in the input sensing insulating pattern IDP.

The antireflection layer RPL may include a light-blocking pattern BMP, a color filter layer CFL, and a top coating layer OC. The antireflection layer RPL may be configured to prevent external light from being reflected by the display module DPM.

The light-blocking pattern BMP may be disposed on the input sensing protection layer ISC and may overlap with the input sensing insulating pattern IDP. The light-blocking pattern BMP may be configured to absorb light. Light incident from outside may be absorbed by the light-blocking pattern BMP and might not be reflected.

The color filter layer CFL may include a first color filter CF1, a second color filter CF2, and a third color filter CF3. The color filter layer CFL may be disposed on the input sensing protection layer ISC.

The shape of the color filter layer CFL may vary depending on the shape of the underlying layers. The color filter layer CFL may be formed using liquid-phase color filter base material. The shape of the color filter base material may vary depending on the underlying structure due to the influence of gravity, surface tension, and surface energy. The color filter base material may be cured to form the color filter layer CFL.

For example, the shape of the color filter layer CFL may vary based on the shape of the input sensing portion ISP. The upper surface of the color filter layer CFL might not be flat. A portion of the upper surface of the color filter layer CFL that overlaps with the input sensing portion ISP may be convex when viewed in a direction opposite to the third direction DR3 from a top side. A portion of the upper surface of the color filter layer CFL that does not overlap with the input sensing portion ISP may be concave when viewed from a top side in a direction opposite to the third direction DR3. A concave region on the upper surface of the color filter layer CFL may be defined as a groove GRV, which may include a curved surface.

At least a portion of the color filter layer CFL may be disposed within (or overlap in a thickness direction of the display module) the transmission opening POP. For example, at least a portion of the color filter layer CFL may be disposed in the opening defined by the optical pattern. As a result, an increase in the overall thickness of the display module DPM due to the application of the optical pattern may be reduced.

The color filter layer CFL may include an organic material and may include an acrylic-based polymer. The color filter layer CFL may further include at least one of a refractive index modifier, a dye, and a pigment.

The color filter layer CFL may have a third refractive index. The value of the third refractive index may be greater than the value of the second refractive index and may be greater than 1.55 and smaller than or equal to 1.63. Therefore, the path of light emitted from the light-emitting diode LDP may be changed at an interface between the input sensing protection layer ISC and the color filter layer CFL.

The first color filter CF1 may overlap with the first light-emitting diode LD1. The first color filter CF1 may be configured to transmit light of the first wavelength and block light of the second and third wavelengths. Accordingly, light of the first wavelength emitted from the first light-emitting diode LD1 may be emitted to the outside of the display module DPM.

The second color filter CF2 may overlap with the second light-emitting diode LD2. The second color filter CF2 may be configured to transmit light of the second wavelength and block light of the first and third wavelengths. Accordingly, light of the second wavelength emitted from the second light-emitting diode LD2 may be emitted to the outside of the display module DPM.

The third color filter CF3 may overlap with the third light-emitting diode LD3. The third color filter CF3 may be configured to transmit light of the third wavelength and block light of the first and second wavelengths. Accordingly, light of the third wavelength emitted from the third light-emitting diode LD3 may be emitted to the outside of the display module DPM.

The top coating layer OC may be disposed on the color filter layer CFL and may be configured to protect the color filter layer CFL. A lower surface of the top coating layer OC may be in contact with an upper surface of the color filter layer CFL. The lower surface of the top coating layer OC may include a protrusion having a shape corresponding to the groove GRV. The protrusion may include a curved surface. The lower surface of the top coating layer OC might not be flat, whereas the upper surface of the top coating layer OC may be flat. Accordingly, the flatness of the upper surface of the top coating layer OC may be greater than the flatness of the lower surface of the top coating layer OC.

The top coating layer OC may include an organic material and may include an acrylic-based polymer. The top coating layer OC may further include a refractive index modifier.

The top coating layer OC may have a fourth refractive index. The value of the fourth refractive index may be greater than the value of the third refractive index and may be greater than 1.63 and smaller than or equal to 1.90. Therefore, the path of light emitted from the light-emitting diode LDP may be changed at the interface between the color filter layer CFL and the top coating layer OC.

As a result, the second refractive index may have a value between the first refractive index and the third refractive index, and the third refractive index may have a value between the second refractive index and the fourth refractive index.

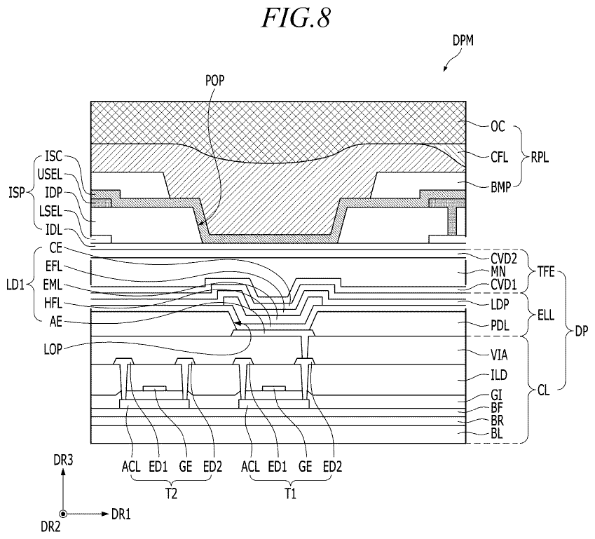

FIG. 8 is an enlarged view showing specific configurations within the AA region of FIG. 7 in more detail. Referring to FIG. 8, the display module DPM may include a display panel DP, an input sensing portion ISP, and an antireflection layer RPL. In FIG. 8, the circuit layer CL, the first light-emitting diode LD1, and the encapsulation layer TFE of the display panel DP may be illustrated in greater detail.

The circuit layer CL may include a base BL, a barrier layer BR, a buffer layer BF, a gate insulating layer GI, an interlayer insulating layer ILD, a circuit insulating layer VIA, a first transistor T1, and a second transistor T2.

The first transistor T1 and the second transistor T2 may be configured to transmit electrical signals. The first transistor T1 and the second transistor T2 may include a plurality of active regions ACL, a plurality of first electrodes ED1, a plurality of control electrodes GE, and a plurality of second electrodes ED2.

The base BL may serve as a foundation for the circuit layer CL. For example, other components of the circuit layer CL may be stacked on the base BL. The base BL may include an organic layer and/or an inorganic layer. The organic layer may include an organic material, for example, polyimide. The inorganic layer may include an inorganic material.

The barrier layer BR may be disposed on the base BL and may be configured to prevent the ingress of moisture or other external contaminants. The barrier layer BR may include inorganic insulating materials such as silicon oxide and silicon nitride.

The buffer layer BF may be disposed on the barrier layer BR and may be configured to obstruct impurities introduced from below from migrating upward. Therefore, components disposed on the buffer layer BF may be protected. The buffer layer BF may include inorganic insulating materials such as silicon oxide and silicon nitride.

The plurality of active regions ACL may be disposed on the buffer layer BF. The plurality of active regions ACL may include polysilicon or amorphous silicon. Alternatively, the plurality of active regions ACL may include a metal oxide semiconductor. Each of the plurality of active regions ACL may include a channel region that serves as a moving path for electrons or holes and first and second ion-doped regions disposed across the channel region.

The gate insulating layer GI may cover the buffer layer BF and the plurality of active regions ACL. The gate insulating layer GI may include an organic film and/or an inorganic film and may include a plurality of inorganic thin films. The plurality of inorganic thin films may include a silicon nitride layer and a silicon oxide layer.

The plurality of control electrodes GE may be disposed on the buffer layer BF and may overlap with the plurality of active regions ACL. Moreover, the plurality of control electrodes GE may include molybdenum (Mo).

The interlayer insulating layer ILD may cover the gate insulating layer GI and the plurality of control electrodes GE. The interlayer insulating layer ILD may include an organic film and/or an inorganic film and may include a plurality of inorganic or organic thin films. The plurality of inorganic thin films may include a silicon nitride layer and a silicon oxide layer.

The plurality of first electrodes ED1 and the plurality of second electrodes ED2 may be disposed on the interlayer insulating layer ILD. The plurality of first electrodes ED1 and the plurality of second electrodes ED2 may be electrically connected to the plurality of active regions ACL through a plurality of contact holes defined in the interlayer insulating layer ILD. The plurality of first electrodes ED1 and second electrodes ED2 may include a metal.

The circuit insulating layer VIA may cover the interlayer insulating layer ILD, the plurality of first electrodes ED1, and the plurality of second electrodes ED2. The circuit insulating layer VIA may include an organic film and/or an inorganic film and may provide a flat surface. The number of circuit insulating layers VIA may be increased as needed.

The first light-emitting diode LD1 may include an anode electrode AE, a hole functional layer HFL, a light-emitting layer EML, an electron functional layer EFL, and a cathode electrode CE. Although not depicted in FIG. 8, the second light-emitting diode LD2 and the third light-emitting diode LD3 shown in FIG. 7 may have the same layered structure as the first light-emitting diode LD1.

The anode electrode AE may be disposed on a portion of the circuit insulating layer VIA. For example, the anode electrode AE may be disposed within the plurality of light-emitting openings LOP. Moreover, the anode electrode AE may be electrically connected to one of the plurality of second electrodes ED2 through a contact hole defined in the circuit insulating layer VIA. Accordingly, the anode electrode AE may be configured to receive electrical signals from the first transistor T1 and the second transistor T2.

Although the first transistor T1 and the second transistor T2 are illustrated as examples in FIG. 8, the structures of the first transistor T1 and the second transistor T2 are not necessarily limited thereto. In FIG. 8, the first transistor T1 is depicted to be in direct contact with the anode electrode AE via one of the plurality of second electrodes ED2, but this is due to the sectional view illustration. In practice, the first transistor T1 may be connected with the anode electrode AE through another transistor. However, the present disclosure is not necessarily limited thereto, and in other embodiments, the first transistor T1 may be in direct contact with the anode electrode AE via one of the first electrodes ED1.

The hole functional layer HFL may be disposed on the anode electrode AE and may be configured to assist in the movement of holes generated at the anode electrode AE. For example, the hole functional layer HFL may facilitate the reception of holes injected from the anode electrode AE and facilitate the movement of the holes. The hole functional layer HFL may have a multilayer structure, for example, including a hole injection layer and a hole transport layer.

The light-emitting layer EML may be disposed on the hole functional layer HFL and may be configured to emit light. The light-emitting layer EML may include an organic luminescent material or quantum dots. Accordingly, the light-emitting diode LD may be an organic light-emitting diode (OLED) or a quantum dot light-emitting diode (QLED).

The electron functional layer EFL may be disposed on the light-emitting layer EML and may be configured to assist in the movement of electrons generated at the cathode electrode CE. For example, the electron functional layer EFL may facilitate the reception of electrons injected from the cathode electrode CE and facilitate the movement of the electrons. The electron functional layer EFL may have a multilayer structure, for example, including an electron injection layer and an electron transport layer.

The cathode electrode CE may be disposed on the electron functional layer EFL. The cathode electrode CE may have low resistance to facilitate the flow of current. The cathode electrode CE may be as a common electrode. Therefore, the plurality of light-emitting diodes LD1, LD2, LD3 illustrated in FIG. 7 may share the cathode electrode CE.

The encapsulation layer TFE may include a first inorganic encapsulation layer CVD1, an organic encapsulation layer MN, and a second inorganic encapsulation layer CVD2. Although it is illustrated as an example in FIG. 8 that the encapsulation layer TFE includes two inorganic encapsulation layers CVD1, CVD2 and one organic encapsulation layer MN, the disclosure is not necessarily limited thereto. For example, the encapsulation layer TFE may include three inorganic encapsulation layers and two organic encapsulation layers, in which case the inorganic and organic encapsulation layers may be alternately stacked.

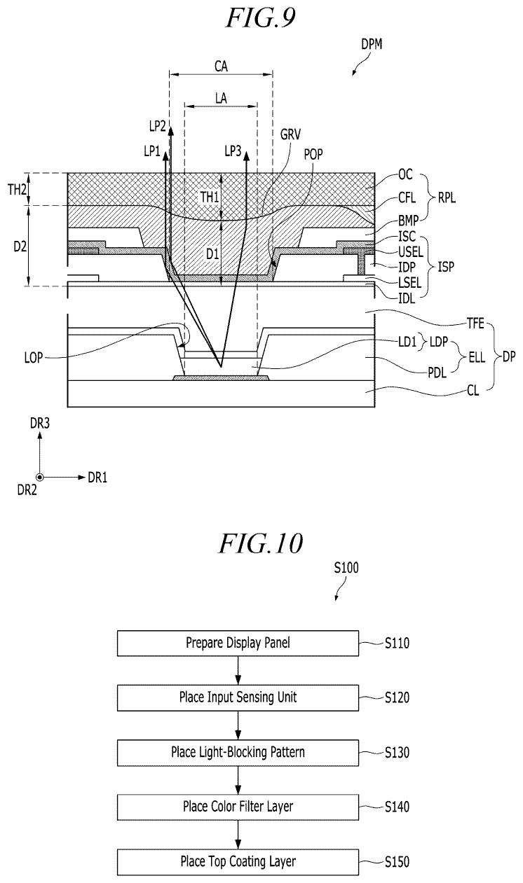

FIG. 9 illustrates an optical path in the enlarged view of region AA of FIG. 7. Referring to FIG. 9, a light-emitting region LA and a concave region CA may be defined in the display module DPM. Additionally, light emitted from the first light-emitting diode LD1 may be emitted along a first optical path LP1, a second optical path LP2, and a third optical path LP3.

The light-emitting region LA may be defined as a region that does not overlap with the pixel defining layer PDL and may correspond to a region overlapping with the light-emitting opening LOP. The first light-emitting diode LD1 may be located in the light-emitting region LA, and thus light may be emitted from the light-emitting region LA.

The concave region CA may be defined as a region that does not overlap with the input sensing insulating pattern IDP and may correspond to a region overlapping with the transmission opening POP. The concave region CA may also overlap with the light-emitting region LA.

An inner surface of the input sensing insulating pattern IDP may be positioned adjacent to the boundary of the concave region. The inner surface of the input sensing insulating pattern IDP may be a surface that defines the transmission opening POP and may contact the input sensing protection layer ISC.

The refractive index of the input sensing insulating pattern IDP may be smaller than the refractive index of the input sensing protection layer ISC. Therefore, light emitted along the first optical path LP1 may undergo total internal reflection at the inner surface of the input sensing insulating pattern IDP. The angle between the light emitted along the first optical path LP1 and the third direction DR3 may be reduced, and therefore the light emitted along the first optical path LP1 may be emitted toward the front of the display module DPM. As a result, the brightness of light emitted toward the front of the display module DPM may be enhanced.

The input sensing protection layer ISC may include an inclined surface. The inclined surface of the input sensing protection layer ISC may be adjacent to the inner surface of the input sensing insulating pattern IDP and may be parallel to the inner surface of the input sensing insulating pattern IDP. The inclined surface of the input sensing protection layer ISC may be in contact with the color filter layer CFL.

The refractive index of the input sensing protection layer ISC may be smaller than the refractive index of the color filter layer CFL. Therefore, light emitted along the second optical path LP2 may undergo total internal reflection at the inclined surface of the input sensing protection layer ISC. The angle between the light emitted along the second optical path LP2 and the third direction DR3 may also be reduced.

A groove GRV may be formed at a region of the upper surface of the color filter layer CFL that overlaps with the concave region CA. The upper surface of the color filter layer CFL overlapping with the concave region CA may be spaced apart from the upper surface of the encapsulation layer TFE by a first distance D1. The upper surface of the color filter layer CFL that does not overlap with the concave region CA may be spaced apart from the upper surface of the encapsulation layer TFE by a second distance D2. The first distance D1 may be smaller than the second distance D2.

A protrusion corresponding to the shape of the groove GRV formed on the upper surface of the color filter layer CFL may be formed on the lower surface of the top coating layer OC. A portion of the top coating layer OC that overlaps with the concave region CA may have a first thickness TH1. Another portion of the top coating layer OC that does not overlap with the concave region CA may have a second thickness TH2, which may be smaller than the first thickness TH1. The lower surface of the top coating layer OC may be in contact with the upper surface of the color filter layer CFL. The sum of the first distance D1 and the first thickness TH1 and the sum of the second distance D2 and the second thickness TH2 may be substantially equal. Accordingly, the upper surface of the top coating layer OC may be flat.

The refractive index of the color filter layer CFL may be smaller than the refractive index of the top coating layer OC. Therefore, light emitted along the third optical path LP3 may be refracted at the upper surface of the color filter layer CFL. For example, due to the groove GRV, a portion of the top coating layer OC may act as a convex lens when viewed in a third direction DR3 from underneath the top coating layer OC. Thus, light incident on the groove GRV may be refracted and emitted along the third optical path LP3. The angle between the light emitted along the third optical path LP3 and the third direction DR3 may be reduced.

Thus, transmission openings POP result in sidewalls in input sensing insulating pattern IDP and input sensing protective layer ISC that light emitting from the display panel DP interacts with. By forming layers to have progressively higher indices of refraction, rays emitting from the display panel may totally reflect off these sidewalls, thereby improving light extraction efficiency and brightness.

Although only the first light-emitting diode LD1 is illustrated in FIG. 9 and is described with reference to FIG. 9, the above description is not necessarily limited to the first light-emitting diode LD1. Light emitted from the second light-emitting diode LD2 and the third light-emitting diode LD3 of FIG. 7 may also be emitted along optical paths corresponding to the first optical path LP1, the second optical path LP2, and the third optical path LP3. Therefore, the brightness of light emitted toward the front of the display module DPM may be enhanced.

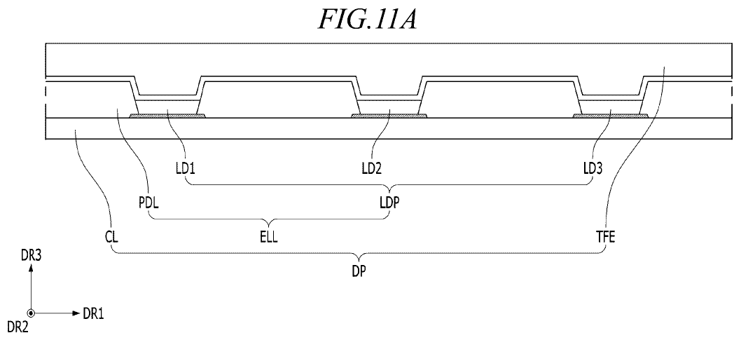

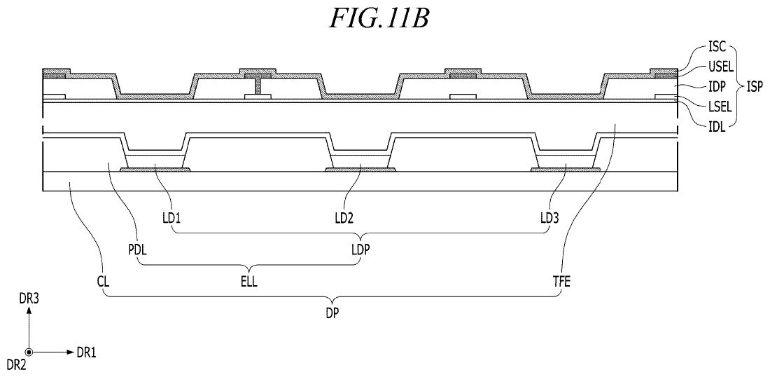

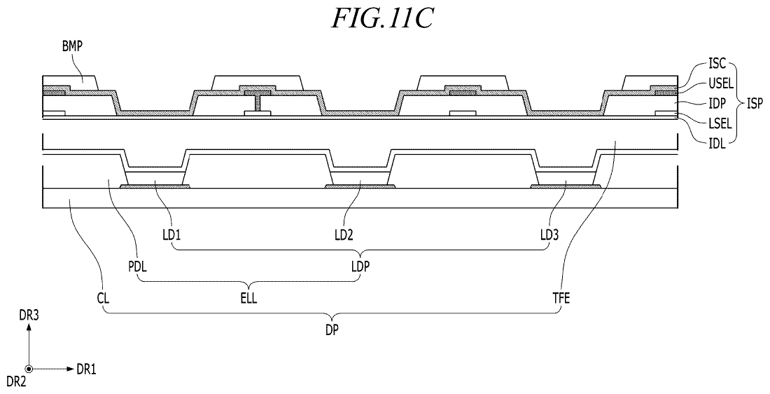

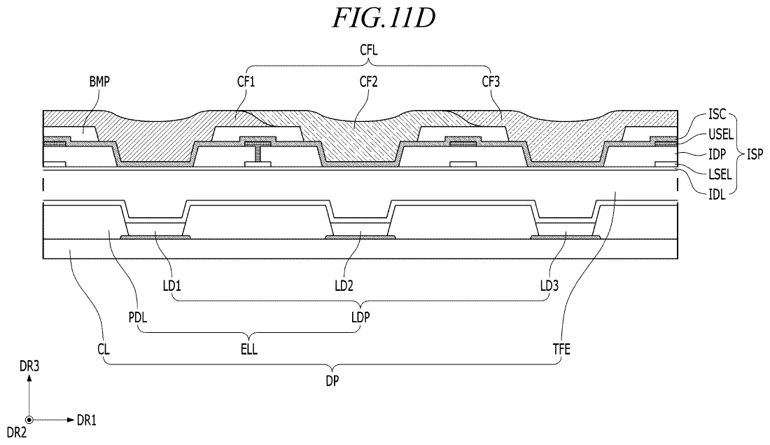

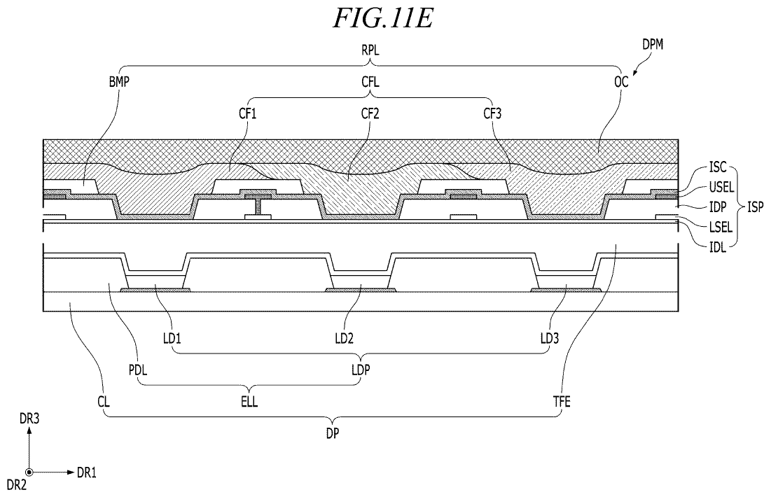

FIG. 10 is a flowchart illustrating a method S100 of manufacturing a display module according to an embodiment of the present disclosure. FIGS. 11A to 11E are cross-sectional views schematically illustrating respective steps of the method S100 of manufacturing a display module according to an embodiment of the present disclosure.

The method of manufacturing an electronic device according to an embodiment of the present disclosure will now be described with reference to FIG. 10 and FIGS. 11A to 11E. The same reference numerals are used for components described with reference to FIGS. 1 through 9 to the extent that an element is not described in detail with respect to this figure, it may be understood that the element is at least similar to a corresponding element that has been described elsewhere within the present disclosure.

Referring to FIG. 10, the method S100 of manufacturing the electronic device may include a preparation step S110, an input sensing portion placement step S120, a light-blocking pattern placement step S130, a color filter layer placement step S140, and a top coating layer placement step S150.

Referring to FIGS. 10 and 11A, in the preparation step S110, a display panel DP may be prepared.

Referring to FIGS. 10 and 11B, in the input sensing portion placement step S120, an input sensing portion ISP may be disposed on the display panel DP. The input sensing portion ISP may be formed by sequentially placing an input sensing insulating layer IDL, a lower sensing electrode LSEL, an input sensing insulating pattern IDP, an upper sensing electrode USEL, and an input sensing protection layer ISC.

Referring to FIGS. 10 and 11C, in the light-blocking pattern placement step S130, a light-blocking pattern BMP may be placed.

Referring to FIGS. 10 and 11D, in the color filter layer placement step S140, a color filter layer CFL may be placed. The color filter layer CFL may be formed by sequentially placing a first color filter CF1, a second color filter CF2, and a third color filter CF3. The sequence of placing the color filters CF1, CF2, CF3 as described above is merely illustrative and may be modified.

Referring to FIGS. 10 and 11E, in the top coating layer placement step S150, a top coating layer OC may be placed. The upper surface of the top coating layer OC may be flat and may be planarized through a separate process.

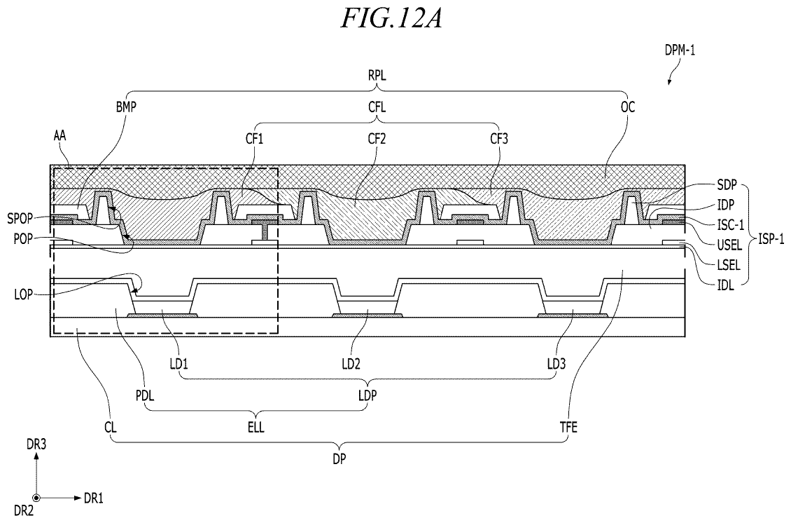

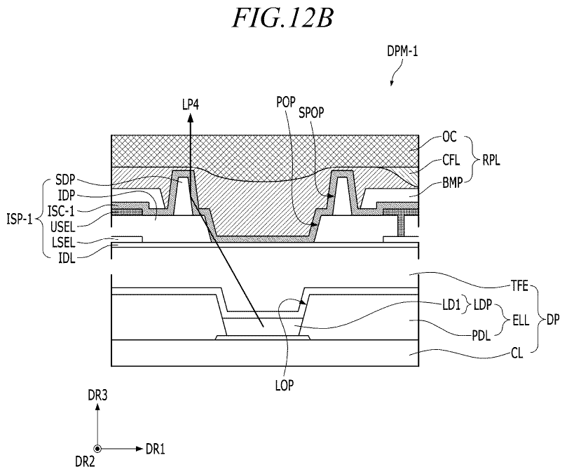

FIG. 12A is a cross-sectional view schematically illustrating a display module DPM-1 according to an embodiment of the present disclosure. FIG. 12B illustrates an optical path in an enlarged view of region AA of FIG. 12A.

Referring to FIG. 12A, an input sensing portion ISP-1 may further include a sub-input sensing insulating pattern SDP. An input sensing protection layer ISC-1 may cover an input sensing insulating pattern IDP, the sub-input sensing insulating pattern SDP, and an upper sensing electrode USEL.

The sub-input sensing insulating pattern SDP may be disposed on the input sensing insulating pattern IDP and might not overlap with a lower sensing electrode LSEL. The inclination angle of the sub-input sensing insulating pattern SDP may be greater than that of the input sensing insulating pattern IDP. The sub-input sensing insulating pattern SDP may be disposed near a transmission opening POP and may have a refractive index corresponding to the first refractive index.

A sub-transmission opening SPOP may be defined in the sub-input sensing insulating pattern SDP. The sub-transmission opening SPOP may overlap with the transmission opening POP and may also overlap with a pixel defining layer PDL.

Referring to FIG. 12B, light emitted from a first light-emitting diode LD1 may be emitted along a fourth optical path LP4. Although light emitted from the first light-emitting diode LD1 may also be emitted along optical paths corresponding to the first optical path LP1, the second optical path LP2, and the third optical path LP3 of FIG. 9, these paths are omitted in FIG. 12B for clarity.

The refractive index of the sub-input sensing insulating pattern SDP may be smaller than the refractive index of the input sensing protection layer ISC-1. Accordingly, light emitted along the fourth optical path LP4 may undergo total internal reflection at a side surface of the sub-input sensing insulating pattern SDP. The angle between the light emitted along the fourth optical path LP4 and the third direction DR3 may be reduced. Therefore, the light emitted along the fourth optical path LP4 may be emitted toward the front of the display module DPM-1. As a result, the brightness of light emitted toward the front of the display module DPM-1 may be enhanced.

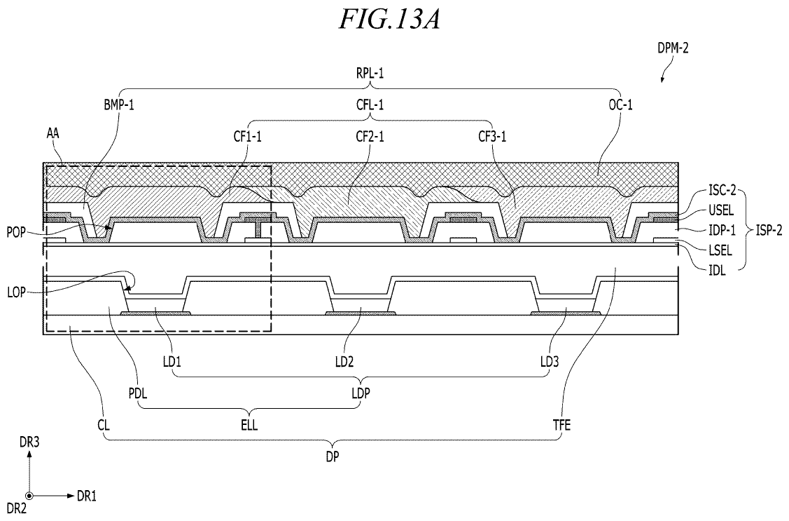

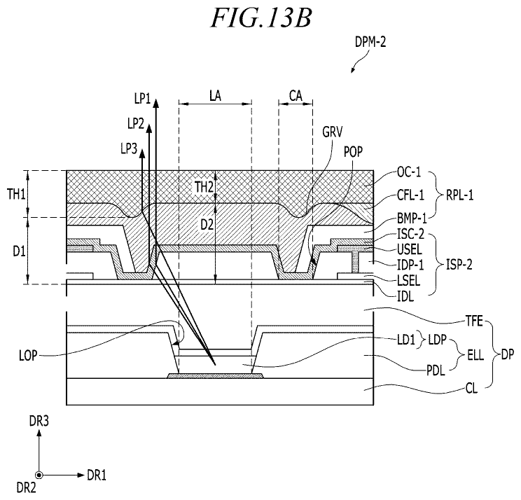

FIG. 13A is a cross-sectional view schematically illustrating a display module DPM-2 according to an embodiment of the present disclosure. FIG. 13B illustrates an optical path in an enlarged view of region AA of FIG. 13A.

Referring to FIG. 13A, an input sensing portion ISP-2 may include an input sensing insulating pattern IDP-1 and an input sensing protection layer ISC-2. An antireflection layer RPL-1 may include a light-blocking pattern BMP-1, a color filter layer CFL-1, and a top coating layer OC-1.

The input sensing insulating pattern IDP-1 may overlap with a pixel defining layer PDL and with a plurality of light-emitting openings LOP.

The input sensing insulating pattern IDP-1 may have a fifth refractive index. The fifth refractive index may be greater than 1.63 and smaller than or equal to 1.90. The fifth refractive index may be greater than sixth through eighth refractive indices described below and may correspond to a high refractive index. The input sensing insulating pattern IDP-1 may be a high-refractive optical pattern.

The input sensing protection layer ISC-2 may cover the input sensing insulating pattern IDP-1 and an upper sensing electrode USEL. The input sensing protection layer ISC-2 may have a sixth refractive index, which may be smaller than the fifth refractive index. Accordingly, the optical path of light emitted from a light-emitting diode LDP may be altered at an interface between the input sensing insulating pattern IDP-1 and the input sensing protection layer ISC-2. For example, the path of light may change at an inner surface of the input sensing insulating pattern IDP-1 that defines a transmission opening POP.

The light-blocking pattern BMP-1 may be disposed on the input sensing protection layer ISC-2. At least a portion of the light-blocking pattern BMP-1 may overlap with the input sensing insulating pattern IDP-1.

The color filter layer CFL-1 may include a first color filter CF1-1, a second color filter CF2-1, and a third color filter CF3-1. The color filter layer CFL-1 may have a seventh refractive index, which may be smaller than the sixth refractive index. The seventh refractive index may be greater than 1.55 and smaller than or equal to 1.63. Therefore, the path of light emitted from the light-emitting diode LDP may change at an interface between the input sensing protection layer ISC-2 and the color filter layer CFL-1.

The top coating layer OC-1 may be disposed on the color filter layer CFL-1. The top coating layer OC-1 may have an eighth refractive index, which may be smaller than the seventh refractive index. The eighth refractive index may be greater than or equal to 1.30 and smaller than or equal to 1.55. Therefore, the optical path of light emitted from the light-emitting diode LDP may change at an interface between the color filter layer CFL-1 and the top coating layer OC-1.

As a result, the sixth refractive index may be between the fifth refractive index and the seventh refractive index, and the seventh refractive index may be between the sixth refractive index and the eighth refractive index.

Referring to FIG. 13B, a light-emitting region LA and a concave region CA may be defined in the display module DPM-2. Light emitted from a first light-emitting diode LD1 may be emitted along a first optical path LP1, a second optical path LP2, and a third optical path LP3.

In FIG. 13B, the light-emitting region LA and the concave region CA might not overlap with each other.

An inner surface of the input sensing insulating pattern IDP-1 may be located near the boundary of the concave region CA. The inner surface of the input sensing insulating pattern IDP-1 may contact the input sensing protection layer ISC-2.

The refractive index of the input sensing insulating pattern IDP-1 may be greater than that of the input sensing protection layer ISC-2. Accordingly, light emitted along the first optical path LP1 may be refracted at the inner surface of the input sensing insulating pattern IDP-1. The angle between the light emitted along the first optical path LP1 and the third direction DR3 may be reduced.

An inclined surface may be placed on the input sensing protection layer ISC-2 in contact with the inner surface of the input sensing insulating pattern IDP-1. The inclined surface of the input sensing protection layer ISC-2 may also contact the color filter layer CFL-1.

The refractive index of the input sensing protection layer ISC-2 may be greater than that of the color filter layer CFL-1. Accordingly, light emitted along the second optical path LP2 may be refracted at the inclined surface of the input sensing protection layer ISC-2. The angle between the light emitted along the second optical path LP2 and the third direction DR3 may be reduced.

The refractive index of the color filter layer CFL-1 may be greater than that of the top coating layer OC-1. Therefore, light emitted along the third optical path LP3 may be refracted at an upper surface of the color filter layer CFL-1. For example, due to a groove GRV, a portion of the top coating layer OC may function as a concave lens when viewed in the third direction DR3 from an underside corresponding to the light emitting diodes LDP. Therefore, light incident on the groove GRV may be refracted and emitted along the third optical path LP3. The angle between the light emitted along the third optical path LP3 and the third direction DR3 may be reduced. Accordingly, the brightness of light emitted toward the front of the display module DPM-2 may be enhanced.

Thus, the locations of the transmission openings POP of the input sensing insulating pattern IDP-1 with respect to the light emitting openings LOP may be changed in addition to having reduced refractive indices in progressing from the light source to the front of the display module and electronic device. As in the earlier embodiments, this produces total internal reflection of sidewalls of the input sensing insulating pattern IDP-1 and the input sensing protection layer ISC-2 that improve light extraction efficiency and brightness.

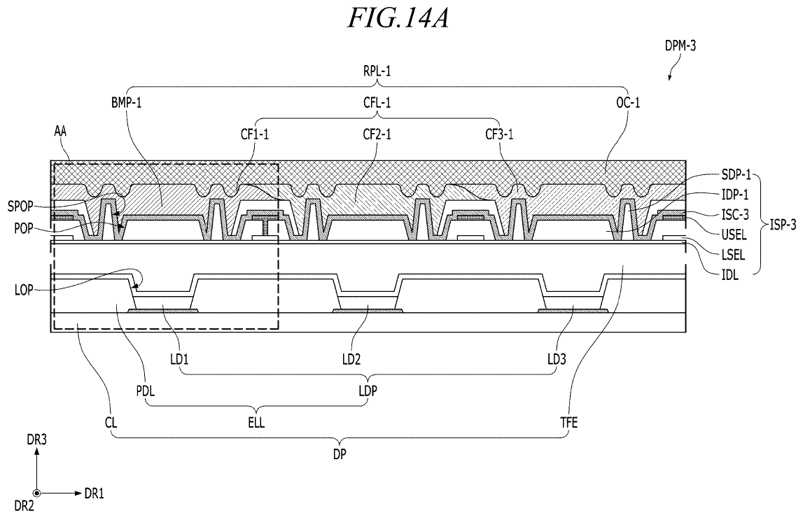

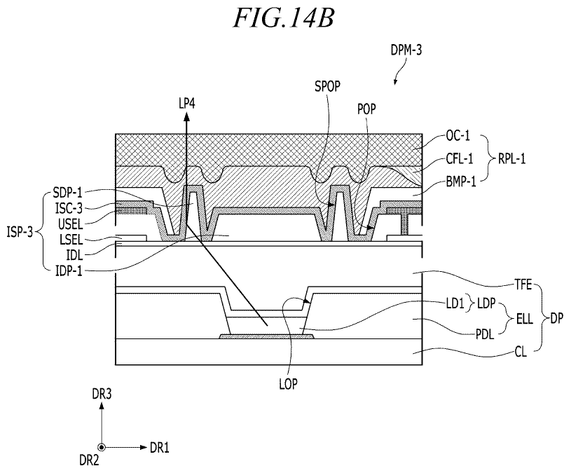

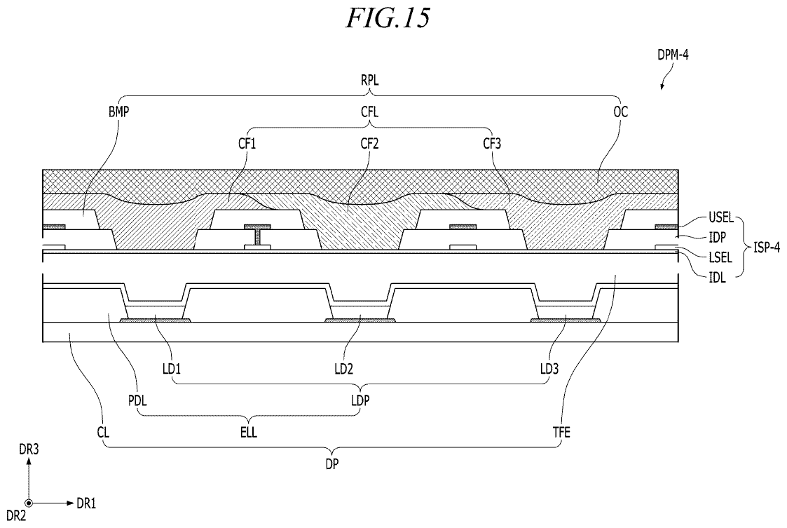

FIG. 14A is a cross-sectional view schematically illustrating a display module DPM-3 according to an embodiment of the present disclosure. FIG. 14B illustrates an optical path in an enlarged view of region AA of FIG. 14A.

Referring to FIG. 14A, an input sensing portion ISP-3 may include the input sensing insulating pattern IDP-1 described with reference to FIG. 13A. The input sensing portion ISP-3 may further include a sub-input sensing insulating pattern SDP-1. An input sensing protection layer ISC-3 may cover the input sensing insulating pattern IDP-1, the sub-input sensing insulating pattern SDP-1, and an upper sensing electrode USEL. An antireflection layer RPL-1 may be the same as the antireflection layer RPL-1 described with reference to FIG. 13A.

The sub-input sensing insulating pattern SDP-1 may be disposed on an input sensing insulating layer IDL and might not overlap with the input sensing insulating pattern IDP-1. The sub-input sensing insulating pattern SDP-1 may overlap with a transmission opening POP. The height of the sub-input sensing insulating pattern SDP-1 may be greater than that of the input sensing insulating pattern IDP-1. The distance between an upper surface of the sub-input sensing insulating pattern SDP-1 and an upper surface of an encapsulation layer TFE may be greater than the distance between an upper surface of the input sensing insulating pattern IDP-1 and the upper surface of the encapsulation layer TFE.

A sub-transmission opening SPOP may be defined in the sub-input sensing insulating pattern SDP-1 and may overlap with the input sensing insulating pattern IDP-1.

The inclination angle of a sub-input sensing insulating pattern SDP-1 may be greater than the inclination angle of a input sensing insulating pattern IDP-1. The refractive index of the sub-input sensing insulating pattern SDP-1 may correspond to the fifth refractive index.

Referring to FIG. 14B, light emitted from a first light-emitting diode LD1 may be emitted along a fourth optical path LP4. While light emitted from the first light-emitting diode LD1 may be emitted along optical paths corresponding to the first, second, and third optical paths LP1, LP2, LP3 described with reference to FIG. 13B, these paths are not depicted in FIG. 14B for clarity.

The refractive index of the sub-input sensing insulating pattern SDP-1 may be greater than the refractive index of the input sensing protection layer ISC-3. Accordingly, light emitted along the fourth optical path LP4 may be refracted at a side surface of the sub-input sensing insulating pattern SDP-1. The angle between the light emitted along the fourth optical path LP4 and the third direction DR3 may be reduced. Therefore, the light emitted along the fourth optical path LP4 may be emitted toward the front of the display module DPM-3. As a result, the brightness of the light emitted toward the front of the display module DPM-3 may be enhanced.

FIG. 15 is a cross-sectional view schematically illustrating a display module DPM-4 according to an embodiment of the present disclosure. Referring to FIG. 15, an input sensing portion ISP-4 may include an input sensing insulating layer IDL, a lower sensing electrode LSEL, an input sensing insulating pattern IDP, and an upper sensing electrode USEL. The input sensing portion ISP-4 of FIG. 15 may correspond to the input sensing portion ISP in FIG. 7 with the input sensing protection layer ISC omitted.

The input sensing protection layer ISC may be an optional element, depending on the properties of underlying components. For example, if the input sensing insulating pattern IDP and the upper sensing electrode USEL exhibit excellent chemical resistance, the input sensing protection layer ISC might be omitted.

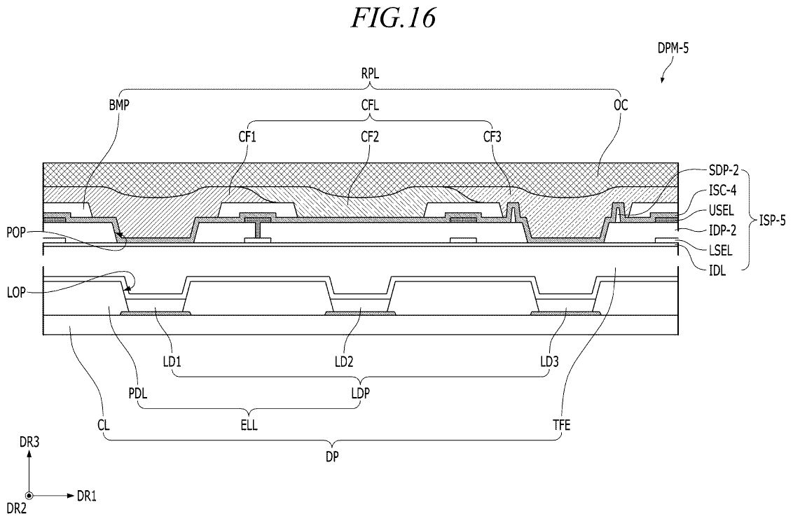

FIG. 16 is a cross-sectional view schematically illustrating a display module DPM-5 according to an embodiment of the present disclosure. Referring to FIG. 16, the input sensing portion ISP-5 may include an input sensing insulating pattern IDP-2, a sub-input sensing insulating pattern SDP-2, and an input sensing protection layer ISC-4. The configuration of the input sensing portion ISP-5 may vary depending on the configuration of a light-emitting diode LDP.

A transmission opening POP may be defined in a portion of the input sensing insulating pattern IDP-2 overlapping with a first light-emitting diode LD1 and in a portion of the input sensing insulating pattern IDP-2 overlapping with a third light-emitting diode LD3. The transmission opening POP might not be defined in a portion of the input sensing insulating pattern IDP-2 that overlaps with a second light-emitting diode LD2.

The sub-input sensing insulating pattern SDP-2 may be disposed near the transmission opening POP overlapping with the third light-emitting diode LD3.

The input sensing protection layer ISC-4 may cover the input sensing insulating pattern IDP-2, the sub-input sensing insulating pattern SDP-2, and the upper sensing electrode USEL.

Accordingly, light of the first wavelength, light of the second wavelength, and light of the third wavelength may be emitted, respectively, along different optical paths. As a result, the light of each wavelength may be guided in different directions, thereby optimizing the light emission from the display module DPM-5.

Therefore the design of the input sensing insulating pattern IDP-2 may vary depending on the color of the light-emitting diode to control the light extraction efficiency and brightness.

It should be noted that the configuration for optimizing the light emitted from the display module DPM-5 is not necessarily limited to the aforementioned description. FIG. 16 merely illustrates one example, and the configuration of the input sensing portion ISP-5 is not necessarily limited thereto. For example, the configuration of an antireflection layer RPL may also vary depending on the configuration of the light-emitting diode LDP.

The display device according to the embodiments may be applied to various electronic devices. An electronic device according to an embodiment may include the aforementioned display device and may further include additional modules or devices with supplementary functions beyond the display device.

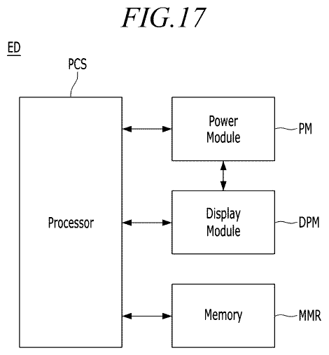

FIG. 17 is a block diagram illustrating an electronic device ED according to an embodiment of the present disclosure. Referring to FIG. 17, the electronic device ED according to one embodiment may include a display module DPM, a processor PCS, a memory MMR, and a power module PM.

The processor PCS may include at least one of a central processing unit (CPU), an application processor (AP), a graphic processing unit (GPU), a communication processor (CP), an image signal processor (ISP), and a controller.

The memory MMR may have data and information necessary for the operation of the processor PCS or the display module DPM stored therein. When the processor PCS executes an application stored in the memory MMR, image data signals and/or input control signals may be transmitted to the display module DPM. The display module DPM may be configured to process the received signals and output image information through a display screen.

The power module PM may include a power supply module, such as a power adapter or battery device, and a power conversion module configured to convert the supplied power to generate power required for operating the electronic device ED.

At least one of the above-described components of the electronic device ED may be included in the display device according to the embodiments described above. Additionally, some of the individual modules functionally included in one module may be integrated into the display device, while others may be provided separately from the display device. For example, the display device may include the display module DPM, whereas the processor PCS, the memory MMR, and the power module PM may be provided as other components within the electronic device ED.

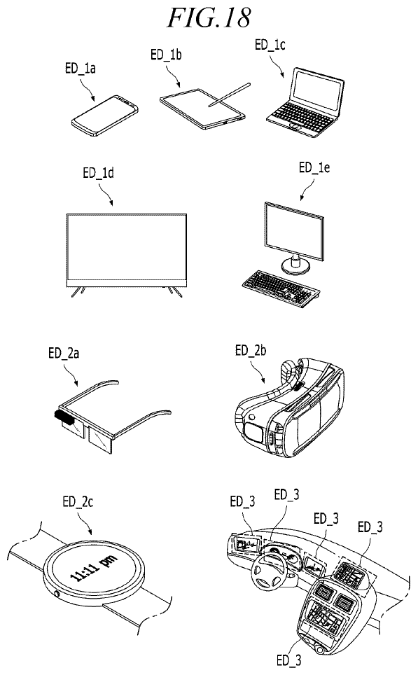

FIG. 18 illustrates various examples of an electronic device ED according to embodiments of the present disclosure. Referring to FIG. 18, various electronic devices to which the display device according to the embodiments is applied may include not only image-displaying electronic devices, such as a smartphone ED_1a, a tablet ED_1b, a laptop computer ED_1c, a television (TV) ED_1d, and a desktop monitor ED_1e, but also wearable electronic devices including a display module, such as smart glasses ED_2a, a head-mounted display ED_2b, and a smartwatch ED_2c. Furthermore, the display device may be applied to automotive electronic devices ED_3 including a display module, such as an instrument cluster, center fascia, center information display (CID) disposed on a dashboard, or a room mirror display.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display module comprising:
a base;
a light-emitting diode disposed on the base that emits light;
an encapsulation layer covering the light-emitting diode;
a lower sensing electrode disposed on the encapsulation layer;
an input sensing insulating pattern comprising an organic material, the input sensing insulating pattern being disposed on the encapsulation layer, the input sensing insulating pattern covering the lower sensing electrode, and the input sensing insulating pattern having a transmission opening defined therein;
an upper sensing electrode disposed on the input sensing insulating pattern;
a color filter layer disposed on the input sensing insulating pattern; and
a top coating layer disposed on the color filter layer,
wherein a refractive index of the color filter layer is between a refractive index of the input sensing insulating pattern and a refractive index of the top coating layer.

2. The display module of claim 1, wherein at least a portion of the color filter layer is disposed within the transmission opening.

3. The display module of claim 2, further comprising:
a pixel defining layer disposed on the base and having a light-emitting opening defined therein,
wherein the transmission opening overlaps with the pixel defining layer in a thickness direction of the display module.

4. The display module of claim 3, wherein
a portion of an upper surface of the color filter layer that overlaps the transmission opening in a thickness direction of the display module is spaced apart from an upper surface of the encapsulation layer by a first distance, and
another portion of the upper surface of the color filter layer that does not overlap the transmission opening in a thickness direction of the display module is spaced apart from the upper surface of the encapsulation layer by a second distance greater than the first distance.

5. The display module of claim 4, wherein a portion of the upper surface of the color filter layer that overlaps the transmission opening in the thickness direction of the display module has a curved surface.

6. The display module of claim 5, wherein a flatness of an upper surface of the top coating layer is greater than a flatness of a lower surface of the top coating layer.

7. The display module of claim 6, further comprising:
an input sensing driving circuit that detects a change in capacitance formed between an external object and each of the lower sensing electrode and the upper sensing electrode.

8. The display module of claim 7, wherein
a refractive index of the input sensing insulating pattern is smaller than a refractive index of the top coating layer, and
the input sensing insulating pattern does not overlap the light-emitting opening in the thickness direction of the display module.

9. The display module of claim 8, wherein
the refractive index of the input sensing insulating pattern is greater than or equal to 1.30 and smaller than or equal to 1.55,
the refractive index of the color filter layer is greater than 1.55 and smaller than or equal to 1.63, and
the refractive index of the top coating layer is greater than 1.63 and smaller than or equal to 1.90.

10. The display module of claim 8, further comprising:
a sub-input sensing insulating pattern having a sub-transmission opening defined therein that overlaps the transmission opening in the thickness direction of the display module, wherein the sub-input sensing insulating pattern does not overlap the lower sensing electrode in a thickness direction of the display module, and
the sub-input sensing insulating pattern is disposed on the input sensing insulating pattern.

11. The display module of claim 7, wherein
a refractive index of the input sensing insulating pattern is greater than a refractive index of the top coating layer, and
the input sensing insulating pattern overlaps the light-emitting opening in the thickness direction of the display module.

12. The display module of claim 11, wherein
the refractive index of the input sensing insulating pattern is greater than 1.63 and smaller than or equal to 1.90,
the refractive index of the color filter layer is greater than 1.55 and smaller than or equal to 1.63, and
the refractive index of the top coating layer is greater than or equal to 1.30 and smaller than or equal to 1.55.

13. The display module of claim 11, further comprising:
a sub-input sensing insulating pattern having a sub-transmission opening defined therein that overlaps the input sensing insulating pattern in the thickness direction of the display module, wherein
the sub-input sensing insulating pattern overlaps the transmission opening and is disposed on the encapsulation layer in the thickness direction of the display module, and
a distance between an upper surface of the input sensing insulating pattern and an upper surface of the encapsulation layer is smaller than a distance between an upper surface of the sub-input sensing insulating pattern and the upper surface of the encapsulation layer.

14. The display module of claim 7, further comprising:
an input sensing protection layer covering the input sensing insulating pattern and the upper sensing electrode, wherein
the input sensing protection layer is disposed between the input sensing insulating pattern and the color filter layer, and
a refractive index of the input sensing protection layer is between a refractive index of the input sensing insulating pattern and a refractive index of the color filter layer.

15. The display module of claim 7, wherein
the light-emitting diode comprises:
a first light-emitting diode that emits light of a first wavelength;
a second light-emitting diode that emits light of a second wavelength different from the first wavelength and
a third light-emitting diode configured to emit light of a third wavelength different from the first wavelength and the second wavelength,
the color filter layer comprises:
a first color filter that transmits the light of the first wavelength and blocks the light of the second wavelength and the third wavelength;
a second color filter that transmits the light of the second wavelength and blocks the light of the first wavelength and the third wavelength; and
a third color filter that transmits the light of the third wavelength and blocks the light of the first wavelength and the second wavelength,
the first color filter overlaps the first light-emitting diode in the thickness direction of the display module,
the second color filter overlaps the second light-emitting diode in the thickness direction of the display module, and
the third color filter overlaps the third light-emitting diode in the thickness direction of the display module.

16. An electronic device comprising:
a base;
a light-emitting diode disposed on the base and that emits light;
an encapsulation layer covering the light-emitting diode;
a lower sensing electrode disposed on the encapsulation layer;
an input sensing insulating pattern disposed on the encapsulation layer, the input sensing insulating pattern covering the lower sensing electrode, and the input sensing insulating pattern having a transmission opening defined therein;
an upper sensing electrode disposed on the input sensing insulating pattern;
a color filter layer disposed on the input sensing insulating pattern; and
a top coating layer disposed on the color filter layer, wherein a portion of the top coating layer that overlaps the transmission opening has a first thickness in a thickness direction of the electronic device,
a portion of the top coating layer that does not overlap the transmission opening in the thickness direction of the electronic device has a second thickness smaller than the first thickness, and
a refractive index of the color filter layer is between a refractive index of the input sensing insulating pattern and a refractive index of the top coating layer.

17. The electronic device of claim 16, wherein
a portion of a lower surface of the top coating layer that overlaps the transmission opening in the thickness direction of the electronic device is spaced apart from an upper surface of the encapsulation layer by a first distance,
a portion of the lower surface of the top coating layer that does not overlap the transmission opening in the thickness direction of the electronic device is spaced apart from the upper surface of the encapsulation layer by a second distance greater than the first distance, and
a sum of the first thickness and the first distance and a sum of the second thickness and the second distance are substantially equal.

18. The electronic device of claim 17, wherein a portion of a lower surface of the top coating layer that overlaps the transmission opening in the thickness direction of the electronic device has a curved surface.

19. The electronic device of claim 18, further comprising:
a pixel defining layer disposed on the base and having a light-emitting opening defined therein, wherein
a refractive index of the input sensing insulating pattern is smaller than a refractive index of the top coating layer, and
the transmission opening overlaps the light-emitting opening in the thickness direction of the electronic device.

20. The electronic device of claim 18, further comprising:
a pixel defining layer disposed on the base and having a light-emitting opening defined therein, wherein
a refractive index of the input sensing insulating pattern is greater than a refractive index of the top coating layer, and
the transmission opening does not overlap the light-emitting opening in the thickness direction of the electronic device.
